(19) United States
(12) Patent Application Publication
(10) Pub. No.: US 2023/0357916 A1
(43) Pub. Date: Nov. 9, 2023

(54) EPITAXIAL STRUCTURE AND METHOD OF MANUFACTURING THE SAME

(71) Applicant: GLOBALWAFERS CO., LTD., Hsinchu City (TW)

(72) Inventors: PO-JUNG LIN, Hsinchu City (TW); HAN-ZONG WU, Hsinchu City (TW)

(73) Assignee: GLOBALWAFERS CO., LTD., Hsinchu City (TW)

(21) Appl. No.: 18/104,462

(22) Filed: Feb. 1, 2023

Related U.S. Application Data
(60) Provisional application No. 63/338,545, filed on May 5, 2022.

(51) Int. Cl. C23C 14/06; C23C 16/02; C23C 16/18; C23C 14/54

(52) U.S. Cl. CPC C23C 14/0617; C23C 16/0281; C23C 16/18; C23C 14/547

(57) ABSTRACT

A method of manufacturing an epitaxial structure includes steps of: A: provide a silicon nitride (SiC) substrate having a carbon face (C-face) without an off-angle; B: form an amorphous structure layer on the C-face of the SiC substrate; C: deposit a first group III nitride layer on the amorphous structure layer; and D: deposit a second group III nitride layer on the first group III nitride layer. By forming the amorphous structure layer, a top surface of the second group III nitride layer could be made to be in a flat and smooth state.

### BACKGROUND OF THE INVENTION

### Technical Field

The present invention relates generally to a method of manufacturing an epitaxial structure, and more particularly to a method of forming a group III nitride layer on a silicon carbide (SiC) substrate.

### Description of Related Art

It is known that group III-V semiconductors, which are gallium nitride (GaN) as an example, are widely applied to different electronic structures, wherein one of the major applicable fields is a High Electron Mobility Transistor (HEMT). The HEMT is a transistor having a two dimensional electron gas (2-DEG) that is located close to a heterojunction of two materials with different energy gaps. As the HEMT makes use of the 2-DEG having a high electron mobility as a carrier channel of the transistor instead of a doped region, the HEMT has features of a high breakdown voltage, the high electron mobility, a low on-resistance, and a low input capacitance.

A HEMT is used as an example for illustration. Generally, in order to reduce a lattice mismatch between a silicon carbide (SiC) substrate and a gallium nitride (GaN) layer, an aluminum nitride (AlN) layer serving as a nucleation layer is grown on the SiC substrate through metal-organic chemical vapor deposition (MOCVD) before growing the GaN layer. However, when a carbon face of the SiC substrate is taken as a growth face for depositing the AlN layer, a metal face of the AlN layer faces the carbon face of the SiC substrate and a nitrogen face of the AlN layer faces upward, making a surface of the GaN layer formed on the AlN layer be not flat or be partially roughened, thereby affecting an epitaxial quality. Therefore, how to provide a method of manufacturing an epitaxial structure, which could form a group III nitride layer having a flat surface on a SiC substrate when taking a carbon face of the SiC substrate as the growth face, is a problem needed to be solved in the industry.

### BRIEF SUMMARY OF THE INVENTION

In view of the above, the primary objective of the present invention is to provide a method of manufacturing an epitaxial structure, which could form a gallium nitride (GaN) layer having a flat surface on a carbon surface of a silicon carbide (SiC) substrate.

The present invention provides a method of manufacturing an epitaxial structure including following steps of: A: provide a silicon carbide (SiC) substrate having a carbon face (C-face) without an off-angle; B: form an amorphous structure layer on the C-face of the SiC substrate; C: deposit a first group III nitride layer on the amorphous structure layer; and D: deposit a second group III nitride layer on the first group III nitride layer.

The present invention further provides an epitaxial structure including a silicon carbide (SiC) substrate, an amorphous structure layer, a first group III nitride layer, and a second group III nitride layer, wherein the SiC substrate has a carbon face (C-face) without an off-angle. The amorphous structure layer is located on the SiC substrate and is connected to the C-face. The first group III nitride layer is located on the amorphous structure layer. The second group III nitride layer is located on the first group III nitride layer.

With the aforementioned design, by forming the amorphous structure layer, the polarity of the first group III nitride layer deposited on the amorphous structure layer is reversed to make the top surface of the second group III nitride layer to be in a flat and smooth state, thereby solving the problem of a conventional manufacturing method that a top surface of a second group III nitride layer deposited on a first group III nitride layer is not flat or is partially roughened as a metal face of the first group III nitride layer faces downward and a nitrogen face of the first group III nitride layer faces upward when directly growing the first group III nitride layer on a carbon face of a silicon carbide substrate.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a flowchart of the method of manufacturing the epitaxial structure according to an embodiment of the present invention;

FIG. 2 is a schematic view showing the epitaxial structure according to an embodiment of the present invention;

FIG. 3 is a photograph showing a sectional view of a part of the epitaxial structure according to the embodiment of the present invention;

FIG. 4A is a photograph showing the top surface of the epitaxial structure according to a comparative example of the present invention; and

FIG. 4B is a photograph showing the top surface of the epitaxial structure according to an embodiment of the present invention.

### DETAILED DESCRIPTION OF THE INVENTION

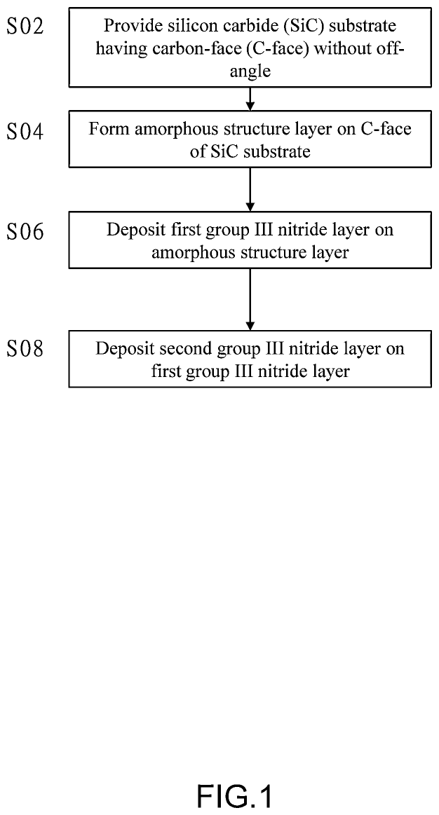

A method of manufacturing an epitaxial structure according to an embodiment of the present invention is illustrated in a flowchart as shown in FIG. 1.

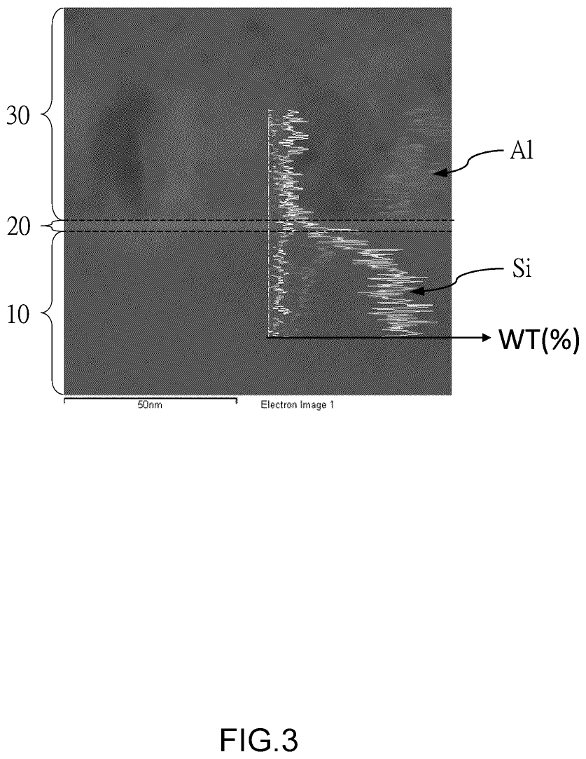

The method of manufacturing the epitaxial structure includes following steps:
step S02: provide a silicon carbide (SiC) substrate 10 having a carbon face (C-face) without an off-angle, wherein the C-face is located on a top face of the SiC substrate 10;
step S04: form an amorphous structure layer 20 on the C-face of the SiC substrate 10, wherein a thickness of the amorphous structure layer 20 is between 2 nm and 5 nm; in the current embodiment, the amorphous structure layer 20 is deposited to form through physical vapor deposition (PVD), wherein the amorphous structure layer 20 is a structure including aluminum, silicon, and nitrogen, and referring to FIG. 3, a content of aluminum of the amorphous structure layer 20 is greater than 50 wt %;
step S06: deposit a first group III nitride layer 30 on the amorphous structure layer 20; in the current embodiment, the step S06 includes depositing the first group III nitride layer 30 having a thickness greater than 50 nm, wherein the first group III nitride layer 30 is aluminum nitride; a full width at half maximum (FWHM) of the first group III nitride layer 30 analyzed through X-ray diffraction analysis is less than 700 arcsec;
the first group III nitride layer 30 could be deposited to form through physical vapor deposition (PVD), metal-organic chemical vapor deposition (MOCVD), or a combination thereof;
for example, the first group III nitride layer 30 could be deposited through PVD and MOCVD, wherein the first group III nitride layer 30 includes a first part and a second part; the step S06 includes after depositing the first part of the first group III nitride layer 30 on the amorphous structure layer 20 through PVD, depositing the second part of the first group III nitride layer 30 on the first part of the first group III nitride layer 30 through MOCVD; the first part has a first thickness, and the second part has a second thickness, and the first thickness is less than the second thickness;
step S08: deposit a second group III nitride layer 40 on the first group III nitride layer 30; the second group III nitride layer 40 is gallium nitride (GaN); in the current embodiment, the step S08 includes analyzing the second group III nitride layer 40 through X-ray diffraction analysis, wherein a FWHM of the second group III nitride layer 40 is less than 200 arcsec, and a root mean square (RMS) roughness of the second group III nitride layer 40 is less than 1 nm.

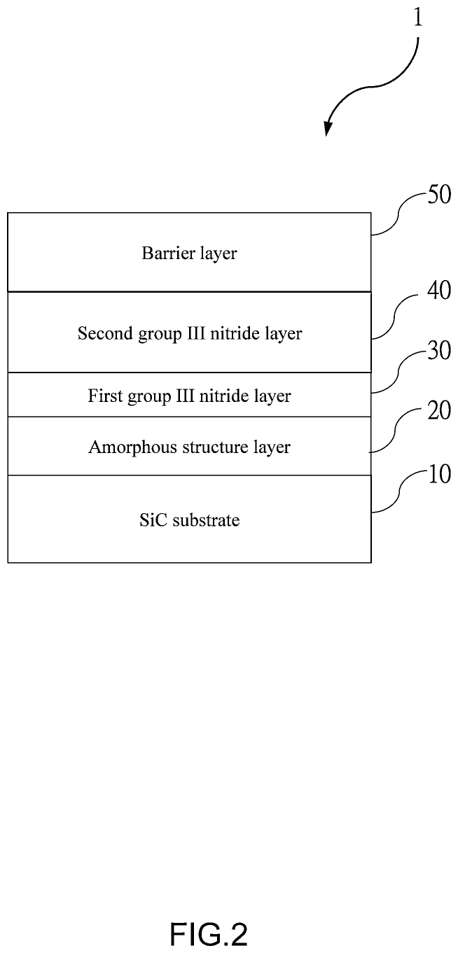

An epitaxial structure 1 manufactured through the method of manufacturing the epitaxial structure is illustrated in FIG. 2 and includes the silicon carbide (SiC) substrate 10, the amorphous structure layer 20, the first group III nitride layer 30, and the second group III nitride layer 40, wherein the SiC substrate 10 has the carbon face (C-face) without an off-angle. The amorphous structure layer 20 is located on the SiC substrate 10 and is connected to the C-face. The first group III nitride layer 30 is located on the amorphous structure layer 20. The second group III nitride layer 40 is located on the first group III nitride layer 30.

Referring to Table 1, a comparative example and an embodiment of the present invention are illustrated as following. The epitaxial structure 1 is a High Electron Mobility Transistor (HEMT) as an example for illustration, wherein the first group III nitride layer 30 is a nucleation layer of the HEMT, and the second group III nitride layer 40 is a buffer layer and a channel layer of the HEMT, and a barrier layer 50 is formed on the second group III nitride layer 40, thereby a two dimensional electron gas (2-DEG) is formed in the channel layer along an interface between the channel layer and the barrier layer 50. In practice, the epitaxial structure 1 could be applied to other electronic structures as well.

### The Comparative Example

In an epitaxial structure in the comparative example, an aluminum nitride (AlN) nucleation layer having a thickness of 0.1 um is formed on a carbon face (C-face) of a silicon carbide (SiC) substrate without an off-angle through MOCVD, then a gallium nitride (GaN) buffer layer having a thickness of 1 um and being doped is formed on the AlN nucleation layer through MOCVD, wherein the GaN buffer layer could be doped by, for example, iron, carbon, or magnesium; then a GaN channel layer having a thickness of 1 um is formed on the doped GaN buffer layer through MOCVD; the SiC substrate has the C-face without the off-angle, and the AlN nucleation layer is deposited on the C-face.

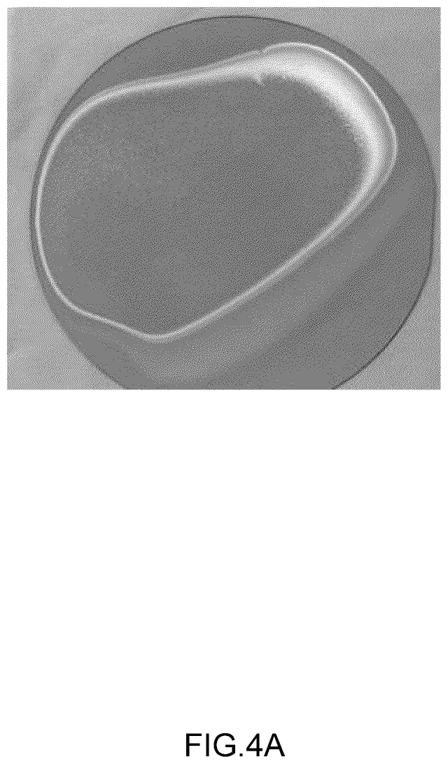

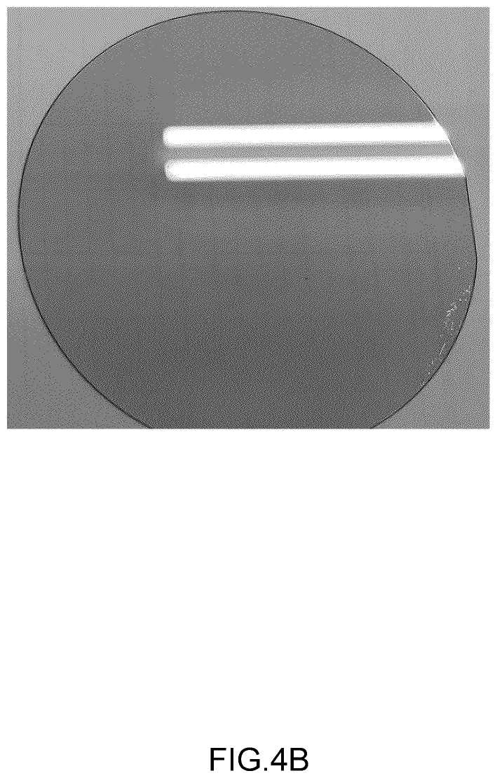

As shown in Table 1, an RMS roughness of a surface of the GaN channel layer of the epitaxial structure in the comparative example is much greater than 1 nm, and as shown in FIG. 4A, the surface of the GaN channel layer is partially roughened. Additionally, a full width at half maximum (FWHM) of the AlN nucleation layer and a FWHM of the GaN channel layer clearly exceed a limit, wherein the FWHM of the AlN nucleation layer is much greater than 700 arcsec, and the FWHM of the GaN channel layer is much greater than 200 arcsec. In other words, when the AlN nucleation layer is directly deposited on the C-face of the SiC substrate through MOCVD, both an epitaxial quality of the AlN nucleation layer and an epitaxial quality of the GaN channel layer are poor, and the RMS roughness of the surface of the GaN channel layer is too large, and the surface of the GaN channel layer is roughened.

### The Embodiment

In an epitaxial structure 1 in the current embodiment, an amorphous structure layer having a thickness between 2 nm and 5 nm is grown to form on a carbon face (C-face) of a silicon carbide (SiC) substrate without an off-angle through PVD, and an aluminum nitride (AlN) nucleation layer having a thickness of 0.1 um is formed on the amorphous structure layer through MOCVD, and then a gallium nitride (GaN) buffer layer having a thickness of 1 um and being doped is formed on the AlN nucleation layer through MOCVD, wherein the GaN buffer layer could be doped by, for example, iron, carbon, or magnesium; then a GaN channel layer having a thickness of 1 um is formed on the doped GaN buffer layer through MOCVD; the SiC substrate has the C-face without the off-angle, and the amorphous structure layer is deposited on the C-face.

As shown in Table 1, an RMS roughness of a surface of the GaN channel layer of the epitaxial structure 1 in the current embodiment is less than 1 nm, and as shown in FIG. 4B, the surface of the GaN channel layer is smooth and flat. Additionally, a full width at half maximum (FWHM) of the AlN nucleation layer is less than 700 arcsec, and a FWHM of the GaN channel layer is less than 200 arcsec. In other words, when the amorphous structure layer is deposited on the C-face of the SiC substrate in advance, the FWHM of the AlN nucleation layer deposited on the amorphous structure layer is made to be less than 700 arcsec by forming the amorphous structure layer, thereby controlling the FWHM of the GaN channel layer to be less than 200 arcsec, and obtaining a flat and smooth top surface of the GaN channel layer; compared with the comparative example, the epitaxial structure 1 in the current embodiment clearly has a greater epitaxial quality.

TABLE 1

| | RMS | FWHM of the AlN | FWHM of the GaN |
|---|---|---|---|
| | roughness | nucleation layer | channel layer |
| | (nm) | (arcsec) | (arcsec) |
| The | >>1 | Clearly exceeding a | Clearly exceeding a |
| comparative | | limit (>>700) | limit (>>200) |
| example | | | |
| The | <1 | <700 | (002):<200 |
| embodiment | | | |

With the aforementioned design, through forming the amorphous structure layer 20, a polarity of the first group III nitride layer 30 deposited on the amorphous structure layer 20 is reversed (i.e., a metal face of the first group III nitride layer 30 faces upward and a nitrogen face of the first group III nitride layer 30 faces downward) to make a top surface of the second group III nitride layer 40 to be in a flat and smooth state, thereby solving the problem of a conventional manufacturing method that a top surface of a second group III nitride layer 40 deposited on the first group III nitride layer 30 is not flat or is roughened as a metal face of the first group III nitride layer 30 faces downward and a nitrogen face of the first group III nitride layer 30 faces upward when directly growing the first group III nitride layer 30 on a carbon face of a silicon carbide substrate.

It must be pointed out that the embodiments described above are only some preferred embodiments of the present invention. All equivalent structures and methods which employ the concepts disclosed in this specification and the appended claims should fall within the scope of the present invention.

What is claimed is:

1. A method of manufacturing an epitaxial structure, comprising steps of:
A: providing a silicon carbide (SiC) substrate having a carbon face (C-face) without an off-angle;
B: forming an amorphous structure layer on the C-face of the SiC substrate;
C: depositing a first group III nitride layer on the amorphous structure layer; and
D: depositing a second group III nitride layer on the first group III nitride layer.

2. The method as claimed in claim 1, further comprising depositing the amorphous structure layer through physical vapor deposition (PVD).

3. The method as claimed in claim 2, wherein a thickness of the amorphous structure layer is between 2 nm and 5 nm.

4. The method as claimed in claim 1, wherein the amorphous structure layer is a structure comprising aluminum, silicon, and nitrogen.

5. The method as claimed in claim 4, wherein a content of aluminum of the amorphous structure layer is greater than 50 wt %.

6. The method as claimed in claim 1, wherein the first group III nitride layer is aluminum nitride.

7. The method as claimed in claim 6, further comprising analyzing the first group III nitride layer through X-ray diffraction analysis, wherein a full width at half maximum (FWHM) of the first group III nitride layer is less than 700 arcsec.

8. The method as claimed in claim 6, further comprising depositing the first group III nitride layer having a thickness greater than 50 nm.

9. The method as claimed in claim 1, wherein the second group III nitride layer is gallium nitride.

10. The method as claimed in claim 9, further comprising analyzing the second group III nitride layer through X-ray diffraction analysis, wherein a full width at half maximum (FWHM) of the second group III nitride layer is less than 200 arcsec.

11. The method as claimed in claim 9, wherein a root mean square (RMS) roughness of the second group III nitride layer is less than 1 nm.

12. The method as claimed in claim 1, further comprising depositing the first group III nitride layer through physical vapor deposition (PVD) and metal-organic chemical vapor deposition (MOCVD).

13. The method as claimed in claim 12, wherein the first group III nitride layer comprises a first part and a second part; the step C comprises after depositing the first part of the first group III nitride layer on the amorphous structure layer through PVD, depositing the second part of the first group III nitride layer through MOCVD.

14. The method as claimed in claim 13, wherein the first part has a first thickness, and the second part has a second thickness; the first thickness is less than the second thickness.

15. An epitaxial structure, comprising:
a silicon carbide (SiC) substrate having a carbon face (C-face) without an off-angle;
an amorphous structure layer located on the SiC substrate and connected to the C-face;
a first group III nitride layer located on the amorphous structure layer; and
a second group III nitride layer located on the first group III nitride layer.

16. The epitaxial structure as claimed in claim 15, wherein the amorphous structure layer is deposited to form through physical vapor deposition (PVD).

17. The epitaxial structure as claimed in claim 16, wherein a thickness of the amorphous structure layer is between 2 nm and 5 nm.

18. The epitaxial structure as claimed in claim 15, wherein the second group III nitride layer is gallium nitride

19. The epitaxial structure as claimed in claim 18, wherein a full width at half maximum (FWHM) of the second group III nitride layer analyzed through X-ray diffraction analysis is less than 200 arcsec.

20. The epitaxial structure as claimed in claim 18, wherein a root mean square (RMS) roughness of the second group III nitride layer is less than 1 nm.
